(19) United States
(12) Patent Application Publication
(10) Pub. No.: US 2013/0260026 A1
(43) Pub. Date: Oct. 3, 2013

(54) Method For Manufacturing A Thin Film On A Substrate

(71) Applicant: SIEMENS AKTIENGESELLSCHAFT, Munchen (DE)

(72) Inventors: Dana Pitzer, Unterschleissheim (DE); Matthias Schreiter, Munchen (DE); Carsten Schuh, Baldham (DE); Thorsten Steinkopff, Egmating (DE)

(73) Assignee: Siemens Aktiengesellschaft, Munchen (DE)

(21) Appl. No.: 13/851,143

(22) Filed: Mar. 27, 2013

(30) Foreign Application Priority Data
Mar. 27, 2012 (DE) 102012204853.7

(51) Int. Cl. C23C 16/40

(52) U.S. Cl. CPC C23C 16/40
USPC 427/126.3; 427/58

(57) ABSTRACT

A method for maufacturing a thin film on a substrate may include: coupling the substrate to a pretensioning facility such that the substrate with the pretensioning facility is isotropically extended in the surface, wherein the substrate is held elastically under pressure with a predetermined pretension; depositing a thin film material on the substrate with a deposition method, in which by applying heat to the thin film material, this is deposited on the substrate so that a thin film with the thin film material is embodied on the substrate; decoupling the substrate from the pretensioning facility; cooling the thin film accompanied by a shrinkage, wherein the predetermined pretension is at least high enough that the appearance of a tensile stress in the thin film is prevented in the case of shrinkage.

### CROSS-REFERENCE TO RELATED APPLICATIONS

This application claims priority to DE Patent Application No. 10 2012 204 853.7 filed Mar. 27, 2012. The contents of which is incorporated herein by reference in its entirety.

### TECHNICAL FIELD

The disclosure relates to a method for manufacturing a thin film on a substrate.

### BACKGROUND

Thin films made of lead zirconate titanate (PZT) are wide-spread in microsystem technology on account of their advantageous physical properties, such as for instance a high electromechanical coupling, a high dielectric constant or a high pyroelectric coefficient. The microsystem usually has a substrate as a carrier for the thin film, wherein the substrate is generally manufactured from silicon. The lead zirconate titanate exists in the thin film as a mixed crystal, which, depending on the zirconium content, has a correspondingly different crystal symmetry. Low zirconium lead zirconate titanate is predominantly present in the tetragonal phase, whereupon zirconium-rich lead zirconate titanate is predominantly present in the rhombohedral phase. If the lead zirconate titanate has a morphotropic composition, for instance with a zirconium content of approximately 50%, tetragonal and rhombohedral metallographic constituents are at the same time present in the thin film as grains. It is known to apply the lead zirconate titanate thin film using a deposition technique, in particular a sputter process, to the substrate, wherein the thin film is typically (111)-textruded. In other words the (111)-directions of all grains in the thin film lie approximately in parallel to the surface normal of the substrate surface. However, the texture of the thin film can be selectively influenced by the use of seed layers.

A preferred direction of polarization is required for the macroscopic piezo and/or pyroelectric functionality of the lead zirconate titanate thin film, wherein the optimal alignment of the preferred direction of the polarization depends on the respectively desired physical effect, which is to be achieved with the thin film, such as for instance the pyroelectric effect. In order to optimize the pyroelectric effect, the preferred direction of polarization of the thin film is aligned in as parallel a manner as possible with the surface normal of the substrate surface. Since the spontaneous polarization of a grid cell lies in the (111)-direction in the rhombohedral phase, a (111)-textruded thin film lends itself to the requirements for an optimal alignment of the polarization in respect of the pyroelectric effect.

The pyroelectric effect of the thin film is defined by a pyroelectric coefficient of the thin film. The size of the pyroelectric coefficients of the thin film is essentially dependent on the composition of the lead zirconate titanate thin film. If the thin film is low in zirconium, the thin film exists in a self-polarized form after its deposition and cooling to room temperature. In other words, the (111)-oriented thin film which emerges during deposition of the lead zirconate titanate no longer changes its polarization state in the subsequent cooling process. In contrast the thin film which is rich in zirconium loses the self-polarization during the cooling process. This loss of self-polarization has proven disadvantageous in this respect as a significantly higher pyroelectric effect than with a tetragonal composition of the thin film is to be expected for (111)-oriented rhombohedral lead zirconate titanate thin films, on account of the optimal alignment of the polarization.

If an infrared light sensor is developed for instance on the basis of the lead zirconate titanate thin film, the size of the pyroelectric coefficients of the thin film linearly assumes the strength of the sensor output signal so that high sensitivity of the sensor can be achieved when reaching the strong pyroelectric effect. Only lead zirconate titanate thin films which have a minimal portion of zirconium are thus considered for the infrared light sensor with the high sensor sensitivity.

### SUMMARY

One embodiment provides a method for manufacturing a thin film on a substrate including: coupling the substrate to a pretensioning facility such that the substrate with the pretensioning facility is isotropically extended in the surface, wherein the substrate with a predetermined pretension is held elastically under stress, wherein the pretensioning facility has a clamping ring, which is applied to the substrate prior to depositing the thin film material, and is isotropically elastically deformed together with the substrate; depositing a thin film material on the substrate using a deposition method, in which the influence of heat on the thin film material causes this to be deposited on the substrate, so that a thin film with the thin film material is embodied on the substrate, wherein the thin film material is deposited on the substrate on the convex side such that the thin film material settles in the interior of the clamping ring and adheres to the inner edge of the clamping ring with a tight connection; decoupling the substrate from the pretensioning facility; and cooling the thin film accompanied by a shrinkage, wherein the predetermined pretension is at least high enough that the appearance of tensile stress in the thin film is prevented upon shrinkage.

In a further embodiment, the pretension is at least high enough that compressive stresses only occur in the thin film after its cooling.

In a further embodiment, the substrate is made of silicon.

In a further embodiment, the thin film material is lead zirconate titanate.

In a further embodiment, the lead zirconate titanate is predominantly in the rhombohedral phase.

In a further embodiment, the thin film is self-polarized following the cooling process.

In a further embodiment, the substrate is pressed onto a convex surface for isotropic convex and elastic deformation of the substrate together with the clamping ring.

In a further embodiment, the surface has a spherical ball shape.

In a further embodiment, the deposition method is a sputter method.

### BRIEF DESCRIPTION OF THE DRAWINGS

Exemplary embodiments will be explained in more detail below based on the schematic drawings, wherein:

FIGS. 1 to 4 show cross-sectional representations in respect of consecutive method steps for manufacturing a thin film on a substrate by using a pretensioning facility.

### DETAILED DESCRIPTION

Some embodiments provide a method for producing a thin film on a substrate, the functionality of which is high.

For example, some embodiments provide a method for manufacturing a thin film on a substrate including the following steps: coupling the substrate to a pretensioning facility such that the substrate with the pretensioning facility is extended isotropically in the surface, wherein the substrate is held elastically under pressure with a predetermined pretension; depositing a thin film material on the substrate using a deposition method, in which by applying heat to the thin film material, this is deposited on the substrate so that a thin film with the thin film material is embodied on the substrate; decoupling the substrate from the pretensioning facility; cooling the thin film accompanied by a shrinkage, wherein the pre-determined pretension is at least high enough that the appearance of tensile stress in the thin film is always prevented with the shrinkage.

The pretension may be at least high enough that compressive stresses only appear in the thin film after its cooling. The substrate may be made of silicon, for example, and the thin film material may be lead zirconate titanate, for example. The lead zirconate titanate may be predominantly present in the rhombohedral phase, i.e., that the lead zirconate titanate exists both in the rhombohedral phase and also in the tetragonal phase, wherein the rhombohedral phase is predominant. The thin film may be self-polarized after the cooling process.

The pretensioning facility may comprise a clamping ring, which is placed on the substrate prior to depositing the thin film material, and is elastically deformed together with the substrate, wherein the thin film material is deposited on the substrate on its convex side such that the thin film material settles in the interior of the clamping ring and adheres to the inner edge of the clamping ring with a tight connection. The substrate may be pressed onto a convex surface for an isotropic and elastic deformation of the substrate together with the clamping ring. The surface herewith may have a spherical ball shape. The deposition method may be a sputter method.

Silicon has a heat expansion coefficient of 2.6 ppm/K, whereas lead zirconate titanate has a thermal expansion coefficient of 6 to 7 ppm/K. If, as is customary, the lead zirconate titanate material is applied to the silicon substrate, wherein particularly with the use of the sputter method, the thin film established by the lead zirconate titanate and the substrate comprising the silicon have a high temperature during the application process. As a result of the heat expansion coefficient of silicon being smaller than that of lead zirconate titanate, with a conventional method for manufacturing the thin film on the substrate, in which the pretensioning facility is not provided, a tensile stress state would develop in the thin film during the cooling process. This results in a polarity reversal of the rhombohedral lead zirconate titanate, as a result of which the pyroelectric effect of the thin film is reduced.

This may be prevented by the provision of the pretensioning facility, wherein the substrate is isotropically extended with the pretensioning facility such that when the thin film is cooled, the appearance of a tensile stress in the thin film is always prevented. The substrate may thus be selectively pretensioned prior to depositing the thin film material with the pretensioning facility such that during the cooling phase, the tensile stress component potentially developing in the thin film is compensated. The tensile stress component may be over-compensated, wherein compressive stresses only appear in thin film after its cooling.

If tensile stresses appear in the thin film, the self-polarization of rhombohedral lead zirconate titanate wears off during the cooling of the thin film following deposition. The reason for this polarization loss lies in the appearance of mechanical tensile stresses in the thin film. If the substrate is formed from silicon and the thin film is formed from lead zirconate titanate, the ratio of the heat expansion coefficients of these materials is therefore different such that when cooling the thin film and the substrate, a biaxial stress state develops in the thin film, by means of which the polarization state is impaired by domains of the thin film.

Tetragonal (111)-textruded lead zirconate titanate and rhombohedral (111)-textruded lead zirconate titanate behave differently in respect of the reorientation of the polarization of domains. In the rhombohedral phase, the (111)-crystal direction is the direction of the spontaneous polarization, as a result of which the alignment of domains at two different angles relative to the surface normal of the substrate is allowed. The influence of the mechanical tensile stresses results in a reduction in stress as a result of flipping domains from one alignment into the other alignment. In the tetragonal phase by contrast, a (001) crystal direction forms the direction of the spontaneous polarization. For the thin film, which has the (111)-oriented crystal direction, only a single possible angle of the domain alignment thus exists relative to the surface normal of the substrate. A switchover of the domains therefore has no influence on the lateral stress state of the thin film, and vice versa. As a result, the polarity state of the tetragonal (111)-textruded lead zirconate titanate also remains under the influence of tensile stresses.

In some embodiments, the polarity reversal of the self-polarized lead zirconate titanate thin film is avoided for the rhombohedral composition and the self-polarity is retained. This is herewith achieved in that the thin film is kept under compressive stress during and in particular after the cooling process, as a result of which the self-polarity of the thin film is also retained in the rhombohedral phase. In the case of pyroelectric applications of the thin film, an improvement in the pyroelectric effect is achieved on account of the optimal alignment of the polarization. Any necessary intermediate layers, which are provided on the thin film, such as for instance electrodes, have no influence on the achieved effect.

The pretensioning facility may be formed by a clamping ring, which rests on the substrate, wherein the clamping ring is pressed onto the spherical ball-shaped surface together with the substrate. After the thin film material is deposited on the substrate and in the clamping ring, the clamping ring, together with the substrate, is received by the spherical ball-shaped surface, wherein the substrate and the clamping ring, together with the thin film embodied in the clamping ring, adopt a 2-dimensional shape. As a result, the curvature radius of the thin film and of the substrate is changed significantly after depositing the thin film material such that the thin film is put under compressive stress, as a result of which tensile stress components possibly developing during the cooling process are compensated. As a result, the depolarization of the thin film is prevented.

As apparent from FIGS. 1 to 4, a pretensioning facility has a clamping ring 1. The clamping ring 1 is manufactured from an elastic material, wherein the clamping ring 1 can emerge in a convex form from a plane, with respect to which the axis of the clamping ring 1 is normal. The pretensioning facility further has a substrate plate 3, which has a surface 4, which is convexly formed such that the surface 4 takes the form of a spherical ball.

A method for manufacturing a thin film 6 on a substrate 2 is shown in its order in FIGS. 1 to 4. According to FIG. 1, the substrate 2 is provided, wherein the clamping ring is placed on the substrate 2 (see arrow 1 in FIG. 1). The clamping ring 1 is embodied to be 2-dimensional so that the plane, relative to which the axis of the clamping ring 1 is normal, extends through the clamping ring 1. The clamping ring 1 has an inner edge 5, wherein the substrate 2 has a large longitudinal extension of this type, and the clamping ring 1 is placed on the substrate 2 such that the inner edge 5 of the clamping ring 1 is arranged entirely on the substrate 2 and does not protrude at all beyond the edge of the substrate 1.

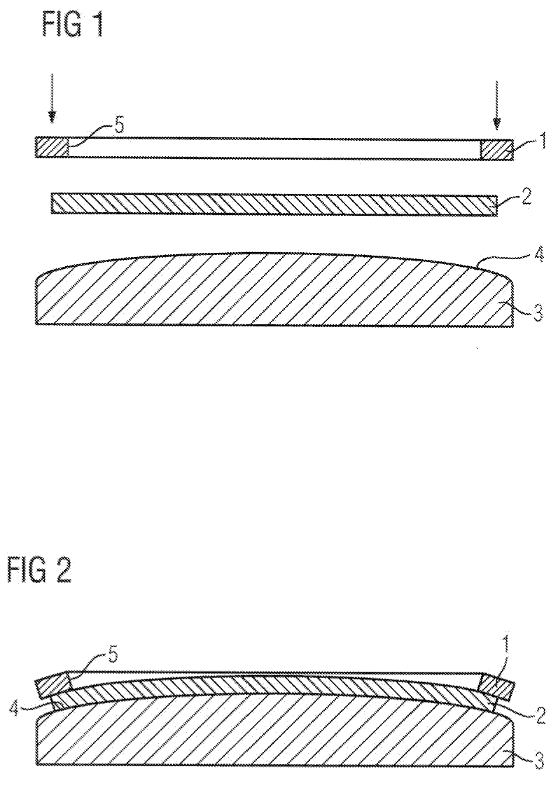

As shown in FIG. 2, in a next method step, the clamping ring 1 together with the substrate 2 is placed on the surface 4 of the substrate plate 3, wherein the substrate 2 is arranged between the clamping ring 1 and the surface 4. The clamping ring 1 is pushed firmly onto the substrate plate 3 such that the substrate 2 nestles against the surface 4 of the substrate plate 3 and thus assumes the convex shape of the surface 4 of the substrate plate 3. As a result, the cross-sections of the clamping ring 1 slant similarly, so that the front faces of the clamping ring 1 are aligned in parallel with the surface 4 of the substrate plate 3. The clamping ring 1 thus assumes a convex structure simulating the surface 4 of the substrate plate 2. As a result, the curvature of the substrate 2 is changed such that the substrate 2 with a predetermined pretension is held elastically under stress.

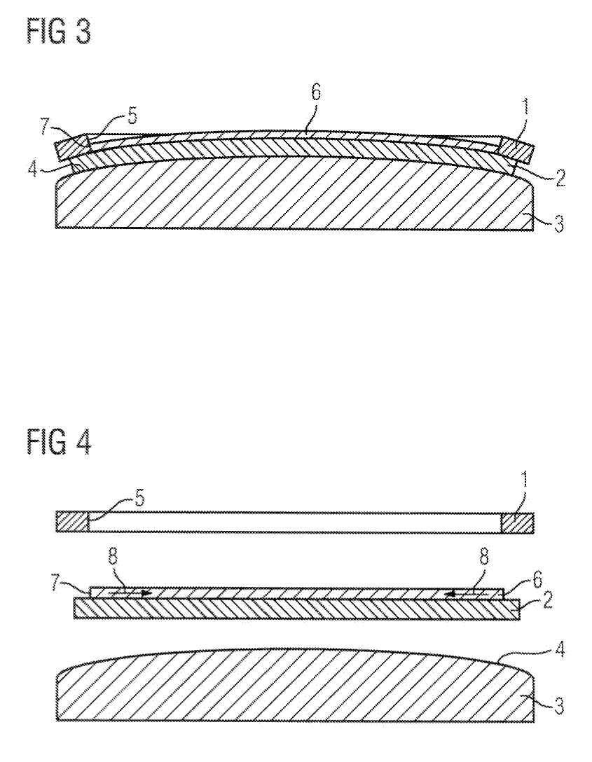

As shown in accordance with FIG. 3, in a next method step, thin film material is deposited on the substrate 2 in the interior of the clamping ring 1, wherein the substrate material covers the substrate 2 with essentially the same thickness so that a thin film 6 is embodied on the substrate 2. The thin film 6 extends completely to the inner edge 5 of the clamping ring 1, wherein the thin film 6 with its thin film edge 7 adheres in a tight-connection to the inner edge 5 of the clamping ring 1. The thin film material is deposited on the substrate 2 using a sputter method for instance, wherein the substrate 2 and the thin film 6 have an essentially higher temperature than the room temperature when depositing the thin film material. When depositing the thin film material on the substrate 2, the substrate plate 3 may have the same temperature as the substrate 2.

According to a further method step, as shown in FIG. 4, the clamping ring 1 together with the substrate 2 is at a distance from the substrate plate 3 (see arrow in FIG. 4). Furthermore, the clamping ring 1 is at a distance from the substrate 2 and the thin layer 6, so that the substrate 2 with the thin film 6 deposited thereupon is spatially isolated from the clamping ring 1 and the substrate plate 3. As a result, the substrate 2 also reassumes a 2-dimensional structure, as a result of which the curvature of the substrate 2 reduces back to zero from the curvature of the surface 4 of the substrate plate 3. As a result of the thin film 6 being applied to the convex side of the substrate 2, compressive stresses form in the thin film 6. The compressive stresses result from the size of the curvature of the surface 4 of the substrate plate 3, wherein the curvature radius of the surface 4 of the substrate plate 3 is predetermined such that only compressive stresses 8 and not tensile stresses occur in the thin film 6 during its cooling.

Although the invention was illustrated and described in more detail by the exemplary embodiments, the invention is not restricted by the disclosed examples and other variations can be derived herefrom by the person skilled in the art without departing from the protective scope of the invention.

What is claimed is:

1. A method for manufacturing a thin film on a substrate comprising:
coupling the substrate to a pretensioning facility such that the substrate with the pretensioning facility is isotropically extended in the surface, wherein the substrate with a predetermined pretension is held elastically under stress, wherein the pretensioning facility has a clamping ring, which is applied to the substrate prior to depositing the thin film material, and is isotropically elastically deformed together with the substrate;
depositing a thin film material on the substrate using a deposition method, in which an influence of heat on the thin film material causes the thin film material to be deposited on the substrate, such that a thin film with the thin film material is embodied on the substrate, wherein the thin film material is deposited on the substrate on a convex side such that the thin film material settles in an interior of the clamping ring and adheres to an inner edge of the clamping ring with a tight connection;
decoupling the substrate from the pretensioning facility; and
cooling the thin film accompanied by a shrinkage, wherein the pre-determined pretension is at least high enough to prevent the appearance of tensile stress in the thin film upon shrinkage.

2. The method of claim 1, wherein the pretension is at least high enough that compressive stresses only occur in the thin film after cooling of the thin film.

3. The method of claim 1, wherein the substrate is made of silicon.

4. The method of claim 1, wherein the thin film material is lead zirconate titanate.

5. The method of claim 4, wherein the lead zirconate titanate is predominantly in the rhombohedral phase.

6. The method of claim 4, wherein the thin film is self-polarized following the cooling process.

7. The method of claim 1, wherein the substrate is pressed onto a convex surface for isotropic convex and elastic deformation of the substrate together with the clamping ring.

8. The method of claim 7, wherein the surface has a spherical ball shape.

9. The method of claim 1, wherein the deposition method is a sputter method.

10. A thin film manufactured on a substrate by a process including:
coupling the substrate to a pretensioning facility such that the substrate with the pretensioning facility is isotropically extended in the surface, wherein the substrate with a predetermined pretension is held elastically under stress, wherein the pretensioning facility has a clamping ring, which is applied to the substrate prior to depositing the thin film material, and is isotropically elastically deformed together with the substrate;
depositing a thin film material on the substrate using a deposition method, in which an influence of heat on the thin film material causes the thin film material to be deposited on the substrate, such that a thin film with the thin film material is embodied on the substrate, wherein the thin film material is deposited on the substrate on a convex side such that the thin film material settles in an interior of the clamping ring and adheres to an inner edge of the clamping ring with a tight connection;
decoupling the substrate from the pretensioning facility; and
cooling the thin film accompanied by a shrinkage, wherein the pre-determined pretension is at least high enough to prevent the appearance of tensile stress in the thin film upon shrinkage.

11. The thin film of claim 10, wherein the pretension is at least high enough that compressive stresses only occur in the thin film after cooling of the thin film.

12. The thin film of claim 10, wherein the substrate is made of silicon.

13. The thin film of claim 10, wherein the thin film material is lead zirconate titanate.

14. The thin film of claim 13, wherein the lead zirconate titanate is predominantly in the rhombohedral phase.

15. The thin film of claim 13, wherein the thin film is self-polarized following the cooling process.

16. The thin film of claim 10, wherein the substrate is pressed onto a convex surface for isotropic convex and elastic deformation of the substrate together with the clamping ring.

17. The thin film of claim 16, wherein the surface has a spherical ball shape.

18. The thin film of claim 10, wherein the deposition method is a sputter method.
